(19) United States
(12) Patent Application Publication
(10) Pub. No.: US 2022/0102639 A1
(43) Pub. Date: Mar. 31, 2022

(54) AQUEOUS SOLUTION PRECURSORS FOR MAKING OXIDE THIN FILMS, AND COMPOSITION AND METHOD FOR MAKING CONDUCTIVE OXIDE THIN FILMS THEREFROM

(71) Applicant: Oregon State University, Corvallis, OR (US)

(72) Inventors: Cory K. Perkins, Corvallis, OR (US); Douglas A. Keszler, Corvallis, OR (US)

(73) Assignee: Oregon State University, Corvallis, OR (US)

(21) Appl. No.: 17/546,729

(22) Filed: Dec. 9, 2021

Related U.S. Application Data
(63) Continuation of application No. PCT/US2020/038092, filed on Jun. 17, 2020.
(60) Provisional application No. 62/862,439, filed on Jun. 17, 2019.

(51) Int. Cl. H01L 51/00; H01L 51/52; H01L 51/56

(52) U.S. Cl. CPC H01L 51/0021; H01L 51/5206; H01L 2251/308; H01L 2251/306; H01L 51/56

(57) ABSTRACT

Reagents and aqueous solutions thereof are described that are useful for aqueous processing to form thin films comprising metal oxides. A film, or layered film, may be incorporated into working devices where the thin film provides useful optical properties, electrical properties, or both.

### CROSS REFERENCE TO RELATED APPLICATION

This application is a continuation of International Application No. PCT/US2020/038092, filed on Jun. 17, 2020, which was published in English under PCT Article 21(2), which in turn claims the benefit of the earlier filing date of U.S. Provisional Application No. 62/862,439, filed on Jun. 17, 2019, which is incorporated herein in its entirety by reference.

### ACKNOWLEDGMENT OF GOVERNMENT SUPPORT

This invention was made with government support under Grant No. CHE-1606982 awarded by the National Science Foundation. The government has certain rights in the invention.

### FIELD

The present invention concerns conductive metal oxides, such as Sn:In₂O₃, Ti:In₂O₃, and Cd₂SnO₄, a method for making such oxides using high-purity solution compositions comprising tin and indium reagents, and a method for forming conductive films comprising metal oxide semiconductors.

### BACKGROUND

Preparation of conductive thin film material is currently done principally by vacuum processing, for example chemical vapor deposition or sputtering. These processes require highly specialized equipment, and high energy requirements make them expensive to operate. Solution processing is both easier and less expensive compared to current vacuum processing methods that are currently used to prepare conductive thin film materials.

Unfortunately, previous solution processing techniques have not proved satisfactory. For example, known solution processing methods fail to produce high-density films. Density is important to the electronic properties of the film. Low-density or porous films may exhibit lower conductivity, lower optical transmittance, and greater surface roughness than high-density equivalent films.

### SUMMARY

Disclosed embodiments concern conductive oxide thin films having high density, high optical transmittance, low surface roughness, and good electronic properties. Embodiments for making such conductive oxide thin films using suitable precursor solutions and solution processing also are disclosed. These precursor solutions are prepared from metal salts, including indium, tin, titanium, and cadmium salts, and numerous combinations thereof. In certain embodiments, these salts have purity levels of at least 99% and higher, up to at least 99.999%. In certain embodiments, these salts may be metal nitrates, or they may be metal halides, such as chlorides. In certain embodiments, the solution is aqueous. In specific disclosed embodiments, the solution is an aqueous solution comprising In(NO₃)₃ and at least one of SnCl₂ or SnF₂. In other disclosed embodiments, the solution is an aqueous solution comprising In(NO₃)₃ and TiCl₃. In still other disclosed embodiments, the solution is an aqueous solution comprising Cd(NO₃)₂ and at least one of SnCl₂ or SnF₂.

Films may be prepared by first preparing a suspension, more typically a solution, of the selected metal salt or salts. The solution is then applied to a substrate to form a film. In some embodiments, the solution is applied by spin coating, roll coating, spray coating, ink-jet printing, mist deposition, dye-slot coating, dip coating, doctor blade application or combinations thereof. The film is then annealed to form a thin film of conductive metal oxide. In some embodiments, the thin film resulting from these solutions is Sn:In₂O₃, Ti:In₂O₃, Cd₂SnO₄, or a combination thereof. In a first disclosed aspect, the invention concerns a solution comprising an aqueous solvent, high-purity SnCl₂, and high-purity In(NO₃)₃. In a second disclosed aspect, the invention concerns an aqueous solution comprising peroxotitanate clusters and high-purity In(NO₃)₃. In a third aspect, the invention concerns an aqueous solution comprising high purity Cd(NO₃)₂, high-purity SnCl₂, and high-purity SnF₂. In a final aspect, these solutions function as precursors to deposit highly conductive thin films that exhibit exceptionally smooth surfaces at thicknesses within the range of 3 nm to 3,000 nm, with certain embodiments having thicknesses >300 nm.

Films created by this process may be incorporated into many useful devices. A person of ordinary skill in the art will understand how to assemble these useful devices. These devices may include, as examples, light emitting diodes, solar cells, and printed circuits.

The foregoing and other objects, features, and advantages of the invention will become more apparent from the following detailed description, which proceeds with reference to the accompanying figures.

### BRIEF DESCRIPTION OF THE DRAWINGS

FIG. 1 is a schematic drawing of an organic light emitting diode (OLED).

FIG. 2 is a schematic drawing of a solar device.

FIG. 3 provides X-ray reflectivity data for Sn:In₂O₃ thin films, annealed at 500° C., confirming low surface roughness in the annealed thin film by the presence of Keissig fringes that extend to 6° 2θ.

FIG. 4 provides the resistivity of an Sn:In₂O₃ film after annealing in a 5% H₂/Ar atmosphere, where the film concentration is 10% wt dopant concentration of Sn.

FIG. 5 provides X-ray diffraction peak intensity data for Sn:In₂O₃ films annealed, such as temperatures between 500° C. and 700° C., establishing that films disclosed are crystalline when annealed at or above 500° C.

FIG. 6 provides optical transmission values through solution-deposited and sputter-deposited Sn:In₂O₃ films for UV and visible wavelengths, demonstrating that solution-deposited films have comparable or superior optical transmission over at least a 400-1000 nm range.

### DETAILED DESCRIPTION

### I. Terms

The following explanations of terms and abbreviations are provided to better describe the present disclosure and to guide those of ordinary skill in the art in the practice of the present disclosure. As used herein, “comprising” means “including” and the singular forms “a” or “an” or “the” include plural references unless the context clearly dictates otherwise. The term “or” refers to a single element of stated alternative elements or a combination of two or more elements, unless the context clearly indicates otherwise.

Unless explained otherwise, all technical and scientific terms used herein have the same meaning as commonly understood to one of ordinary skill in the art to which this disclosure belongs. Although methods and materials similar or equivalent to those described herein can be used to practice or test the present disclosure, suitable methods and materials are described below. The disclosed materials, methods, and examples are illustrative only and are limiting. Other features of the disclosure are apparent from the following detailed description and the claims.

Unless otherwise indicated, all numbers expressing quantities of components, molecular weights, percentages, temperatures, times, and so forth, as used in the specification or claims are understood to be modified by the term “about.” Accordingly, unless otherwise indicated, implicitly or explicitly, the numerical parameters set forth are approximations that may depend on, for example, the desired properties sought and/or limits of detection under standard test conditions/methods. When directly and explicitly distinguishing embodiments from discussed prior art, the embodiment numbers are not approximates unless the word “about” is recited.

Roughness Average, Ra, is the arithmetic average of the absolute values of the profile heights over an evaluation length or area.

RMS Roughness is the root mean square average of film heights over an evaluation length or area.

“Thin,” as used herein with respect to a thin film or thin layer, refers to a film or layer typically having a film thickness or layer thickness of from greater than zero to 3,000 nm, greater than zero to 2,000 nm, greater than zero to 1,000 nm, including 200 nm to 700 nm, or 400 nm to 600 nm, or greater than zero to 500 nm, from greater than zero to 250 nm, or from greater than zero to 100 nm.

“Ultrasmooth” as used herein with respect to the thin film or thin film layer refers to a film or layer typically having an RMS roughness of greater than 0 nm to 10 nm or less, such as greater than 0 nm to 5 nm or less, including greater than 0 nm to 3 nm or less, or greater than 0 nm to 2 nm or less, with certain embodiments having a roughness of greater than 0 nm to 1 nm or less, from greater than zero to 0.75 nm, from 0.1 nm to 0.7 nm, from 0.2 nm to 0.6 nm, from 0.3 nm to 0.6 nm, from 0.4 nm to 0.6 nm, or from 0.4 nm to 0.5 nm. Films having such smooth surfaces provide end-use benefits. For example, low surface roughness prevents loss of optical transmittance due to photon scattering. Low surface roughness additionally improves electrical performance by reducing the likelihood of electrical shorts resulting from poor surface contact.

### II. Description

A. Compositions, Precursor Reagents, Precursor Reagent Compositions Used to Make Compositions, and Films Comprising the Compositions

Disclosed embodiments concern indium oxide (In₂O₃) compositions, tin oxide (SnO₂) composition, indium:tin oxide (Sn:In₂O₃) compositions, titanium:indium oxide (Ti:In₂O₃) composition, cadmium:tin oxide (Cd₂SnO₄) composition, doped versions of these oxide compositions, such as doped indium oxide compositions and doped tin oxide compositions, and precursor reagents and compositions used to make such compositions. The present invention also concerns embodiments of a method for making films, particularly thin films, and even more preferably thin, ultrasmooth films, from solutions comprising In₂O₃, Sn:In₂O₃, Ti:In₂O₃, Cd₂SnO₄, doped In₂O₃, doped SnO₂, doped Sn:In₂O₃, doped Ti:In₂O₃, and doped Cd₂SnO₄. Particular embodiments concern films with useful electronic and optical properties, including doped conductive films, such as doped conductive In₂O₃ films or doped Sn:In₂O₃ films, as well as doped Ti:In₂O₃ and doped Cd₂SnO₄ compositions and films.

A person of ordinary skill in the art will appreciate that compositions comprising two or more metal species may have varying ratios of metal ions. For certain disclosed embodiments:

for Sn:In₂O₃ films, the Sn:In ratio is from about 0.05:1 to about 0.25:1;

for Ti:In₂O₃ films, the Ti:In ratio is from about 0.05:1 to about 0.2:1; and

for Cd₂SnO₄ films, the Cd:Sn ratio is up to about 3.5:1.

Suitable In₂O₃ precursors include any precursor that can be used to produce a desired indium oxide thin film. For particular disclosed embodiments, water soluble precursors are preferred. The soluble indium oxide precursor may be, for example, indium nitrate or an indium halide. The amount of indium oxide precursor used is selected to produce a concentration of In³⁺ in solution suitable to facilitate production of a thin film with desired properties, such as a desired density, a desired thickness, a desired refractive index, and/or an RMS surface roughness. In some embodiments, the amount of indium oxide precursor is selected to produce an In³⁺ concentration in the solution of from greater than zero to 1 M or more, such as from 0.1 M to 0.9 M, from 0.2 M to 0.8 M or from 0.4 M to 0.8 M.

Suitable SnO₂ precursors include any precursor that can be used to produce a desired film, such as a SnO₂ or Sn:In₂O₃ thin film. For particular disclosed embodiments, water soluble precursors are preferred. The soluble tin oxide precursor may be, for example, a tin complex or salt. In some embodiments, the tin compound is a tin halide, such as tin fluoride, tin chloride, tin bromide, or tin iodide; tin chloride hydrate; tin nitrate; tin nitrate hydrate; tin acetate; tin sulfate; or a combination thereof. The amount of tin oxide precursor used is selected to produce a concentration of Sn²⁺ in solution suitable to facilitate production of a thin film with desired properties, such as a desired density, a desired thickness, a desired refractive index, and/or a RMS surface roughness. In some embodiments, the amount of tin oxide precursor is selected to produce a Sn²⁺ concentration in the solution of from greater than zero to 1 M or more, such as from 0.1 M to 0.9 M, from 0.2 M to 0.8 M or from 0.4 M to 0.8 M.

Suitable titanium precursors include any precursor that can be used to produce a desired film, such as a Ti:In₂O₃ thin film. For particular disclosed embodiments, water soluble precursors or aqueous solutions thereof are preferred. The soluble titanium precursor may be, for example, a titanium complex or salt. In some embodiments, the titanium compound is a titanium halide, such as titanium fluoride, titanium chloride, titanium bromide, or titanium iodide; or a combination thereof.

Suitable cadmium precursors include any precursor that can be used to produce a desired cadmium oxide film, such as a Cd₂SnO₄ thin film. For particular disclosed embodiments, water soluble precursors are preferred. The soluble cadmium precursor may be, for example, a cadmium complex or salt. In some embodiments, the cadmium compound is a cadmium halide, such as cadmium fluoride, cadmium chloride, cadmium bromide, or cadmium iodide; or a combination thereof.

Disclosed In₂O₃, Sn:In₂O₃, Ti:In₂O₃, and Cd₂SnO₄ compositions and films made therefrom may include a dopant to improve film properties, such as electrical properties of the film. For certain disclosed embodiments, In₂O₃, Sn:In₂O₃, Ti:In₂O₃, and Cd₂SnO₄ precursor compositions include a doping reagent selected to impart a cadmium or titanium dopant to resultant In₂O₃, Sn:In₂O₃, Ti:In₂O₃, and Cd₂SnO₄ compositions. Doping reagents can include 4⁺, 5⁺, and 6⁺ cations.

Data presented herein establishes that the electrical properties of In₂O₃, Sn:In₂O₃, Ti:In₂O₃, and Cd₂SnO₄ films, including doped composition films, are substantially affected by even trace contaminants. Accordingly, certain disclosed embodiments concern using highly pure precursor reagents, including reagents having a purity of at least 99%, such as 99.5%, 99.9%, 99.99% and 99.999%. Exemplary disclosed embodiments used reagents such as In(NO₃)₃ (99.999%, Alfa-Aesar), SnCl₂ (99.999%, Sigma-Alrich), SnF₂ (99.999%, Sigma-Alrich), TiCl₃ (20% w/v Fisher) and Cd(NO₃)₃ (Alfa-Aesar, 99.99%).

The method for making In₂O₃, Sn:In₂O₃, Ti:In₂O₃, and Cd₂SnO₄ compositions generally comprises dissolving a suitable precursor or precursors in water to make a solution. Agitation may be used to facilitate forming desired precursor compositions such as stirring, shaking, sonication, or a combination thereof. Additionally, or alternatively, a precursor/solvent mixture may be heated to aid solution formation. The mixture may be heated at a temperature suitable to facilitate forming a solution, such as from 25° C. to reflux, typically 100° C. or more, such as from 30° C. to 100° C., from 50° C. to 90° C. or from 70° C. to 90° C. The heating and/or agitation proceeds for a suitable time period to form an acceptable composition, such as a few minutes to 48 hours, from 1 hour or less to 48 hours or more, from 6 hours to 36 hours, from 12 hours to 30 hours or from 18 hours to 24 hours. In some embodiments, a precursor/solvent mixture is heated and/or agitated in a sealed container, for example, to reduce evaporation.

B. Forming a Thin Film

In₂O₃, Sn:In₂O₃, Ti:In₂O₃, and Cd₂SnO₄ compositions and doped variants thereof are deposited onto substrates, and the film coated substrates are then used to form devices, or components of devices, such as electrical devices. The substrate can be any substrate on which a thin film can be formed, such as a silicon, including silica (SiO₂); glass; a metal; a metal alloy; an optical crystal, including non-linear optical crystals; a laser crystal; ceramic substrates; and substrates comprising combinations of such materials. In some embodiments, the substrate is a silicon substrate, such as a silicon wafer. In other embodiments, the substrate is a hydrophobic or hydrophilic glass, such as a silicate glass, i.e. a glass comprising silicon dioxide.

The thin film may be deposited on the substrate by any suitable technique. Suitable techniques include, but are not limited to, spin coating, roll coating, spray coating, ink-jet printing, mist deposition, dye-slot coating, dip coating, doctor blade application and combinations thereof. Particular embodiments of the present invention use spin coating to form films on suitable substrates. Large scale commercial production may use a different technique, such as a roll coater or doctor blade application. For spin coating, a selected composition and amount thereof are droplet dropped onto a substrate surface, and then the surface is rotated at a suitable rotation speed to coat the substrate surface effectively within a period of time suitable to provide a desired film thickness. Spin coating may, for example, be conducted at from about 500 rpm to about 6,000 rpm, such as from 1,000 rpm to 5,000 rpm, 2,000 rpm to 4,000 rpm, with 4,000 rpm being used to form certain disclosed exemplary embodiments. The processing period is typically only a matter of seconds but does depend on the speed of rotation, with typical processing times being from about 1 to about 60 seconds, with certain working embodiments using spin processing parameters of 3,000 rpm for 30 seconds.

For certain disclosed embodiments, the thin film is a dense film, i.e. a substantially non-porous film. Dense films may have densities from greater than 80% up to 100% of the theoretical single crystal density of the material.

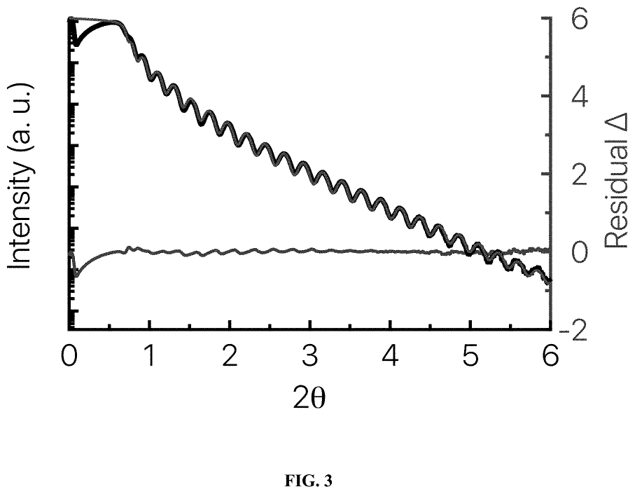

A thin film made by the disclosed method has a substantially smooth surface, preferably an ultrasmooth surface, such as a surface having an RMS roughness value of from greater than zero to 1 nm, such as from greater than zero to less than 1 nm, from greater than zero to 0.75 nm, from 0.1 nm to 0.7 nm, from 0.2 nm to 0.6 nm, from 0.3 nm to 0.6 nm, from 0.4 nm to 0.6 nm, or from 0.4 nm to 0.5 nm. The RMS roughness value may be determined by AFM measurements acquired over a 1×1 μm² area. Alternatively, the RMS surface roughness can be estimated by the presence of Keissig fringes at low values of 20. FIG. 3 shows X-ray reflectivity data for Sn:In₂O₃ thin films, heat processes, such as annealed, at 500° C. As can be seen by the presence of Keissig fringes that extend to 6° 2θ FIG. 3, the film surface is substantially smooth, with a root mean square (RMS) value of 0.4 nm. Such smooth surfaces may be advantageous, for example, for enhancing anti-reflective properties of the film, reducing electrical shorts and/or providing an enhanced interface with a second film or layer that is deposited on top of the thin film.

After deposition, the thin film optionally typically is then heat processed. Disclosed embodiments may be initially exposed to a temperature below the film's annealing temperature to, for example, evaporate some or substantially all of any residual solvent. This initial heating, or “soft baking,” may comprise exposing the film to a suitable temperature, such as from 50° C. to 250° C., or from 100° C. to 200° C., and may proceed for a time period of from greater than zero to the time required to achieve the desired result, such as from greater than zero to at least 5 minutes, or from 1 minute to 2 minutes. The film may be processed at a first temperature for a first period of time, then processed at a second temperature, typically higher than the first temperature, for a second period of time. In some embodiments, the film is processed at a temperature of from 80° C. to 120° C. for a time period of from greater than zero to 3 minutes, such as from 1 to 2 minutes, then exposed to a temperature of from 150° C. to 250° C., such as from 180° C. to 220° C., for a time period of from greater than zero to 3 minutes, such as from 1 to 2 minutes.

The thin film may be exposed to a temperature suitable to anneal the film and produce a film having one or more desired properties, such as to facilitate oxide formation, and/or to improve surface smoothness, film thickness, electrical properties and/or refractive index. The annealing temperature may be selected to ensure that substantially all of the residual components from the precursors, such as nitrates and any added processing aids, are removed. Additionally, or alternatively, the annealing temperature may be selected to either facilitate crystallization, or substantially preclude film crystallization, as desired for the final product. The film may start to crystallize as the annealing temperature approaches the crystallization temperature of the film. As the film starts to crystallize, the refractive index and/or surface RMS roughness may start to increase. Therefore, a suitable annealing temperature is selected to balance these factors as desired for the final product.

To anneal, the film may be processed at an annealing temperature of from 350° C. to 1,000° C. or more, such as from 400° C. to 1,000° C., from 450° C. to 900° C., from 450° C. to 800° C., from 450° C. to 700° C., from 450° C. to 600° C. or from 500° C. to 600° C. In certain disclosed exemplary embodiments, the film was annealed at a temperature of about 500° C. The time period sufficient to anneal the film may be from greater than one minute to 12 hours or more, such as from 5 minutes to 6 hours, from 15 minutes to 4 hours, from 30 minutes to 2 hours, or from 45 minutes to 90 minutes. In certain disclosed embodiments, the film was exposed to a suitable annealing temperature, such as 500° C., for 1 hour.

The annealing may occur in any suitable environment, including air, nitrogen, noble gas, hydrogen, or a suitable mixture thereof. In certain disclosed embodiments, annealing was performed in a controlled atmosphere of mixed hydrogen and argon gas. In some embodiments, the annealing atmosphere was 5% hydrogen gas and 95% argon gas.

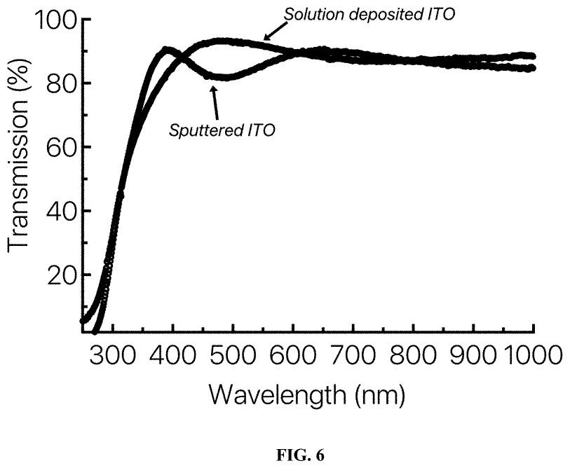

The conductive oxide film produced in this way may, in some embodiments, have high optical transparency. In certain disclosed examples, the optical transmission has been greater than 85% over the visible spectrum. The optical transmittance may be affected by the surface roughness, the thickness, and the total density of the film. FIG. 6 provides the UV-visible optical transmission of a solution deposited Sn:In₂O₃ film, which is comparable to or higher than a commercially-produced film prepared by a vacuum processing method.

The thickness of the film after annealing may be affected by selecting the concentration of the precursors, such as the concentrations of the indium containing precursor, the tin containing precursor, the titanium containing precursor, and/or the cadmium containing precursor, if present. Additional control over the thickness of the film is possible by selecting the spin speed, with lower speeds generally yielding thicker films. In some disclosed embodiments, a speed of 3000 RPM for 30 seconds has been selected. Film layers deposited in this way may, in some embodiments, have a thickness of up to about 50 nm. Where films thicker than those produced by a single spin coating process are desired, the desired thickness can be reached by serially layered multiple films.

C. A Layered Film Comprising Multiple Thin Films

A layered film may comprise multiple thin films, with at least one, some, or all of the films having compositions and/or physical properties of films as disclosed herein, with each thin film being a layer in the layered film. The layered film may comprise two or more layers, such as 2-50 layers, more typically 2 to 10 layers, such as 2, 3, 4, 5, 6, 7, 8, 9, 10 or more layers. Sequential and/or non-sequential layers may have the same or different compositions, such as dopant amounts or metal ion rations, and/or physical and/or optical properties, such as refractive index. The layered film may comprise a composition change and/or gradient across the layers from the substrate to the surface layer. For example, there may be an increasing or decreasing amount of dopant in the layers from the substrate to the surface layer. In some embodiments, the different layers are selected to provide a change and/or gradient of physical and/or optical properties. As used herein with respect to composition or a physical and/or optical property, a gradient across the layers refers to a change from a layer having a first composition and/or property to a second layer having a second composition and/or property where there is one or more intermediate layers, such as 2, 3, 4, 5, 6, 7, 8 or more intermediate layers, having intermediate compositions and/or properties that together with the first and second layers, form a gradual change from the first composition and/or property to the second composition and/or property. The layers may be selected to provide an increasing or decreasing change or gradient of electrical properties or refractive indices across the layers from the substrate to the surface layer. In some embodiments, the layered film comprises multiple compositional and/or property changes and/or gradients across the layers from the substrate to the surface. For example, the layers may be selected to provide a first change and/or gradient that increases a property, such as the refractive indices of the layers, and then a second change and/or gradient that decreases a property, such as the refractive indices of the layers, or vice versa.

A layered film may be made by depositing a first layer on the substrate and heating this layer at a first temperature below an annealing temperature for a time suitable to form a non-annealed layer, as described herein. A second layer can then be deposited on the surface of the first layer. The second layer may then be heated at a second temperature below an annealing temperature, the second temperature being the same or different than the first temperature. If the second layer is the desired outer or surface layer, heating at the second temperature optionally may be omitted. Additional layers can then be deposited by repeating the deposition and heating processes until all the desired layers have been deposited. Once the desired outer or surface layer is deposited, the layered film may be annealed at an annealing temperature, as described herein. The outer or surface layer optionally may be heated at a temperature below the annealing temperature prior to annealing.

In some embodiments of the present invention, layers of the conductive oxide film are added until a desired thickness of up to 1 micron is obtained. In specific examples the total film thickness is between 250 nm and 350 nm.

### III. Device Schematics

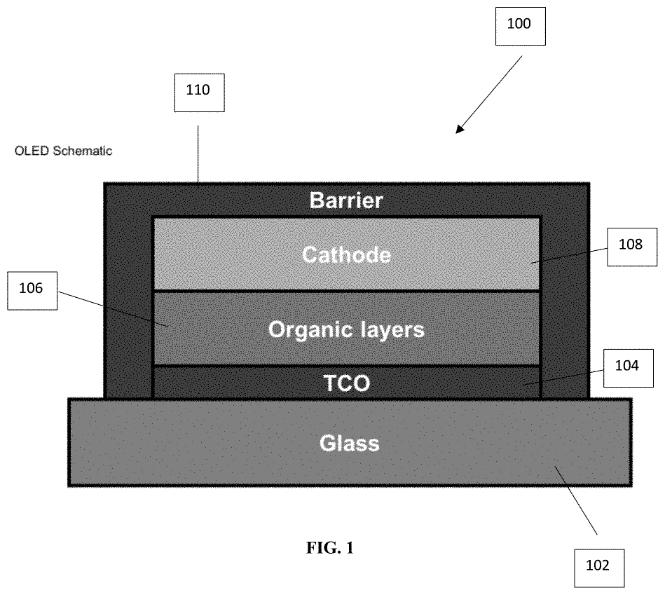

A person of ordinary skill in the art will appreciate that the products, such as thin films, made herein can be used to make a number of useful devices. For example, such products can be used to form light emitting diodes, such as organic light emitting diodes. FIG. 1 provides a schematic drawing illustrating an exemplary OLED 100. OLED 100 comprises a substrate, such as a glass substrate 102. A thin film conductive oxide (TCO) layer 104 according to the present application is formed on the glass substrate 102. An organic layer 106 is then positioned adjacent to the TCO layer 104. OLED 100 also includes a cathode 108 and a barrier layer 110.

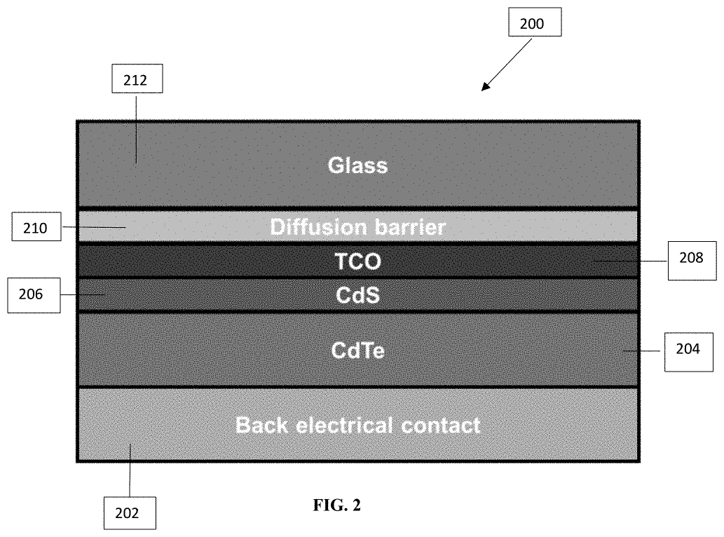

FIG. 2 illustrates an embodiment of a device 200 comprising a TCO according to the present application that is useful for solar applications. Device 200 includes a back electrical contact layer 202, a CdTe layer 204 and a CdS layer 206 positioned adjacent to CdTe layer 204. A TCO layer 208 according to the present application is positioned adjacent to the CdS layer 206. Device 200 also includes a diffusion barrier 210 and a glass substrate 212.

### IV. Examples

The following examples are provided to illustrate features of certain exemplary embodiments according to the present invention. A person of ordinary skill in the art will appreciate that the scope of the invention is not limited to these particular features.

### Example 1

In(NO₃)₃ (99.999%, Alfa-Aesar) and SnCl₂ (99.999%, Sigma-Alrich) were dissolved in deionized water with atomic ratios of Sn:In from 0.05 to 0.25. Solutions were droplet deposited on SiO₂ substrates and then thin films formed by spin coating at 3,000 RPM for 30 seconds. The deposited thin films were heat processed, such as annealed, between 200° C. and 1000° C. Films exhibit very smooth surfaces. FIG. 3 shows X-ray reflectivity data of a film annealed at 550° C. for 1 hour. The derived and low surface roughness (RMS surface roughness=0.4 nm) is visually confirmed by the presence of Kiessig fringes that extend to 6° 2θ.

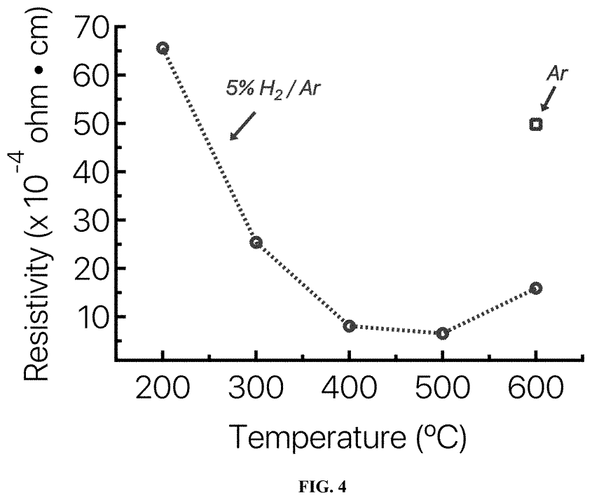

Electrical resistivity of the films as a function of annealing temperature was measured. The lowest resistivity value, ρ=6×10⁴ ohm·cm, occurs at a Sn concentration of 10 at % for a film annealed at 500° C. in 5% H₂/Ar. FIG. 4 shows the effect of annealing temperature on ITO films annealed in 5% H₂/Ar. The Hall mobility of one embodiment of a film according to the present invention was measured to be 21 cm² V⁻¹ s⁻¹ and near that of sputtered ITO after the 500° C. anneal in 5% H₂/Ar.

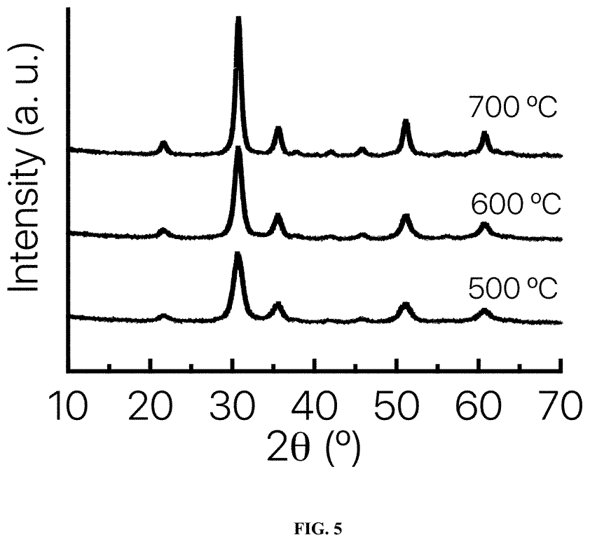

Films produced by this method and annealed at temperatures of 500° C. and higher are crystalline, as shown in FIG. 5 by the presence of peaks in the X-ray diffraction pattern. The resulting film for certain disclosed embodiments was 350 nm thick, and such films had an RMS surface roughness of less than 1 nm, as measured by atomic force microscopy, affirming the X-ray reflectivity data shown in FIG. 3.

Films produced by this method additionally exhibit high optical transmission over the visible spectrum. FIG. 6 shows that solution-deposited Sn:In₂O₃ transmission was >85% between 400-1000 nm, i.e., comparable to or higher than commercial Sn:In₂O₃ films deposited by vapor-phase sputter methods.

### Example 2

In(NO₃)₃ (99.999%, Alfa-Aesar) is dissolved in water and aqueous mixtures of H₂O₂ and TiCl₃ (20% w/v, Fisher) is added to produce Ti:In atomic ratios between 0.05:1 and 0.2:1, respectively. 10%-doped Ti:In₂O₃ films annealed at 500° C. for 1 h have resistivities ≤2.1×10⁻³ ohm·cm and low RMS surface roughness=0.5 nm with thicknesses ranging from 300 nm to 1 μm. Films are crystalline at anneal temperatures of 500° C. and higher.

### Example 3

Cd(NO₃)₂ (99.999%, Alfa-Aesar) is dissolved in water, along with SnCl₂ (99.999%, Sigma-Alrich) and/or SnF₂ (99.99%, Sigma-Alrich). Typical solutions are prepared with Cd:Sn ratios of 2.5:1. Cd₂SnO₄ films annealed at 500° C. for 1 h have resistivities ≤17×10⁻⁴ ohm·cm and high mobility, 35 cm² V⁻¹ s⁻¹. Films feature low RMS surface roughness <0.5 nm with thicknesses ranging from 300 nm to 1 μm. Films are crystalline at anneal temperatures of 500° C. and higher.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

We claim:

1. An aqueous solution for solution processing to form metal oxide films, the solution comprising a metal salt selected from an indium salt, a tin salt, a titanium salt, a cadmium salt, or any combination thereof, wherein the metal salt or salts has a purity greater than 99%.

2. The solution according to claim 1 wherein the metal salt is a nitrate or a halide.

3. The solution according to claim 2 wherein the metal salt is a chloride metal salt.

4. The solution according to claim 1 comprising:
In(NO₃)₃ and at least one of SnCl₂ or SnF₂;
In(NO₃)₃ and TiCl₃; or
Cd(NO₂)₂ and at least one of SnCl₂ or SnF₂.

5. An aqueous-solution produced thin film, comprising Sn:In₂O₃, Ti:In₂O₃, Cd₂SnO₄, or a combination thereof.

6. A method for forming a conductive metal oxide thin film, comprising:
preparing an aqueous solution comprising a metal salt selected from an indium salt, a tin salt, a titanium salt, a cadmium salt, or any combination thereof;
applying the solution to a substrate to form a thin film; and
heating the substrate to form a conductive metal oxide thin film.

7. The method according to claim 6 wherein the metal salt or salts has a purity greater than 99%.

8. The method according to any of claim 6 wherein the metal salt or salts is/are a nitrate or halide.

9. The method according to claim 6 wherein the metal salt or salts is/are chloride metal salts.

10. The method according to claim 6 wherein the aqueous solution comprises:
In(NO₃)₃ and at least one of SnCl₂ or SnF₂;
In(NO₃)₃ and TiCl₃; or
Cd(NO₃)₂ and at least one of SnCl₂ or SnF₂.

11. The method according to claim 6 wherein the solution is applied to a substrate by spin coating, roll coating, spray coating, ink-jet printing, mist deposition, dye-slot coating, dip coating, doctor blade application, or combinations thereof.

12. The method according to claim 6 wherein the metal oxide film comprises Sn:In₂O₃, Ti:In₂O₃, Cd₂SnO₄, or a combination thereof.

13. A conductive metal thin film produced by the method of claim 6 and having an RMS roughness value of from greater than zero to 3 nm.

14. The conductive metal thin film according to claim 13 having an RMS roughness value of 1 nm or less.

15. The conductive metal thin film according to claim 13 having a density of from 80% to 100% of the theoretical single crystal density of the material.

16. A method, comprising:
providing an aqueous solution comprising a metal salt having a purity of greater than 99% selected from an indium salt, a tin salt, a titanium salt, a cadmium salt, or any combination thereof;
applying the solution to a substrate to form a thin film by spin coating, roll coating, spray coating, ink-jet printing, mist deposition, dye-slot coating, dip coating, doctor blade application or combinations thereof;
heating the substrate to form a conductive metal oxide thin film; and
assembling a device comprising the substrate and conductive metal oxide thin film.

17. The method of claim 16 wherein the solution comprises:
an aqueous solution of In(NO₃)₃ and at least one of SnCl₂ or SnF₂;
an aqueous solution of In(NO₃)₃ and TiCl₃, or
an aqueous solution of Cd(NO₃)₂ and at least one of SnCl₂ or SnF₂.

18. The method of claim 16 wherein the oxide metal film comprises Sn:In₂O₃, Ti:In₂O₃, Cd₂SnO₄, or a combination thereof.

19. A device made according to the method of claim 16.

20. The device of claim 19 wherein the device is a light emitting diode, a solar cell or a printed circuit.
